(19) United States
(12) Patent Application Publication
(10) Pub. No.: US 2026/0063720 A1
(43) Pub. Date: Mar. 5, 2026

(54) MALFUNCTION-DIAGNOSING APPARATUS

(71) Applicant: SUBARU CORPORATION, Tokyo (JP)

(72) Inventors: Junpei TSUCHIYA, Tokyo (JP); Takumi TAKADA, Tokyo (JP); Motohiro TAKEUCHI, Tokyo (JP); Takashi KAERIYAMA, Tokyo (JP); Kento ITABASHI, Tokyo (JP)

(21) Appl. No.: 19/264,948

(22) Filed: Jul. 10, 2025

(30) Foreign Application Priority Data
Aug. 28, 2024 (JP) 2024-146849

(51) Int. Cl. G01R 31/34

(52) U.S. Cl. CPC G01R 31/343

(57) ABSTRACT

A malfunction-diagnosing apparatus includes an alternator and a controller. The controller is configured to diagnose a malfunction of the alternator. The alternator includes a power generator configured to generate an alternating-current voltage by using motive power output from an engine, and a rectifier configured to rectify the alternating-current voltage into a direct-current voltage. The rectifier includes a field-effect transistor, and a diode coupled in parallel to the field-effect transistor. The controller is configured to diagnose the malfunction, based on power generation efficiency of the alternator.

### CROSS-REFERENCE TO RELATED APPLICATIONS

The present application claims priority from Japanese Patent Application No. 2024-146849 filed on Aug. 28, 2024, the entire contents of which are hereby incorporated by reference.

### BACKGROUND

The disclosure relates to a malfunction-diagnosing apparatus.

In the related art, a machine in which a metal-oxide-semiconductor field effect transistor (MOSFET) is used for a rectifier of an alternator is proposed (see, for example, Japanese Unexamined Patent Application Publication (JP-A) No. 2014-87093). JP-A No. 2014-87093 describes detection of a short-circuit in the MOSFET based on the voltage of components of the alternator.

### SUMMARY

An aspect of the disclosure provides a malfunction-diagnosing apparatus including an alternator and a controller. The controller is configured to diagnose a malfunction of the alternator. The alternator includes a power generator configured to generate an alternating-current voltage by using motive power output from an engine, and a rectifier configured to rectify the alternating-current voltage into a direct-current voltage. The rectifier includes a field-effect transistor, and a diode coupled in parallel to the field-effect transistor. The controller is configured to diagnose the malfunction, based on power generation efficiency of the alternator.

An aspect of the disclosure provides a malfunction-diagnosing apparatus including an alternator and circuity. The circuity is configured to diagnose a malfunction of the alternator. The alternator includes a power generator configured to generate an alternating-current voltage by using motive power output from an engine, and a rectifier configured to rectify the alternating-current voltage into a direct-current voltage. The rectifier includes a field-effect transistor, and a diode coupled in parallel to the field-effect transistor. The circuity is configured to diagnose the malfunction, based on power generation efficiency of the alternator.

### BRIEF DESCRIPTION OF THE DRAWINGS

The accompanying drawings are included to provide a further understanding of the disclosure and are incorporated in and constitute a part of this specification. The drawings illustrate an embodiment and, together with the specification, serve to describe the principles of the disclosure.

FIG. 1 is a block diagram illustrating an example of the structure of a vehicle;

FIG. 2 illustrates the structure of an alternator;

FIG. 3 is a flowchart illustrating the flow of a malfunction diagnosing process performed by a controller; and

FIG. 4 illustrates a theoretical value map of power generation efficiency.

### DETAILED DESCRIPTION

A diode is coupled in parallel to a MOSFET used for an alternator in order to protect the MOSFET from back electromotive force (surge). Thus, the alternator continues to generate electric power even when an open failure occurs in the MOSFET, because the diode enables rectification. Accordingly, there is a possibility that the open failure in the MOSFET of the alternator cannot be detected by using the method described in JP-A No. 2014-87093.

It is desirable to diagnose a malfunction of an alternator that uses a field-effect transistor.

In the following, an embodiment of the disclosure is described in detail with reference to the accompanying drawings. Note that the following description is directed to an illustrative example of the disclosure and not to be construed as limiting to the disclosure. Factors including, without limitation, numerical values, shapes, materials, components, positions of the components, and how the components are coupled to each other are illustrative only and not to be construed as limiting to the disclosure.

Further, elements in the following example embodiment which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same numerals to avoid any redundant description.

### 1. Structure of Vehicle

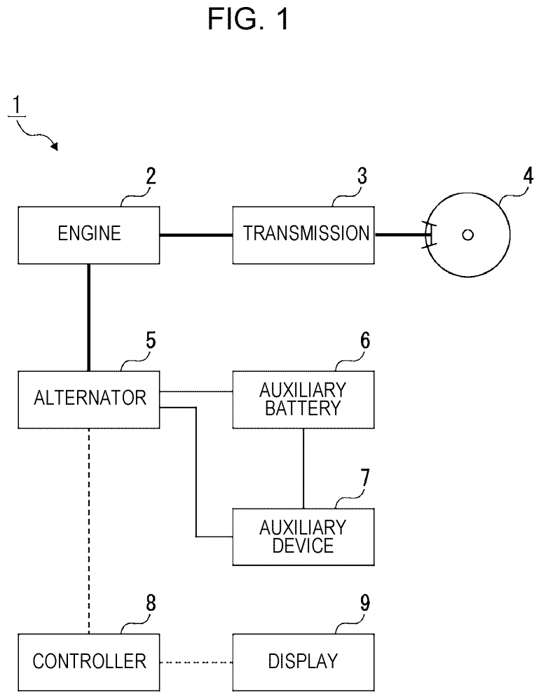

FIG. 1 is a block diagram illustrating an example of the structure of a vehicle 1 according to the emnodiment. In FIG. 1, a thick solid line represents the transmission of motive power, a thin solid line represents the flow of electric power, and a dashed line represents the flow of a signal.

As illustrated in FIG. 1, the vehicle 1 that is an example of a malfunction-diagnosing apparatus includes an engine 2, a transmission 3, a wheel 4, an alternator 5, an auxiliary battery 6, an auxiliary device 7, a controller 8, and a display 9.

For example, the engine 2 is a horizontally opposed engine in which a pair of cylinder groups are horizontally disposed in a left-and-right direction with a crankshaft interposed therebetween. The engine 2 causes a piston to reciprocate due to combustion pressure that is applied when mixed gas of gasoline and air is burnt in the cylinder. The engine 2 acquires motive power by rotating the crankshaft coupled to the piston with a connecting rod interposed therebetween. Examples of the engine 2 may include a series engine and a V engine. The engine 2 may be a diesel engine.

The transmission 3 is coupled to the crankshaft of the engine 2, transmits the motive power from the engine 2 to the wheel 4, and consequently causes the wheel 4 to rotate, and the vehicle 1 travels.

The alternator 5 is coupled to the crankshaft of the engine 2 with an auxiliary belt interposed therebetween. When the motive power of the engine 2 is input via the auxiliary belt, the alternator 5 generates electric power by using the motive power. The electric power generated by the alternator 5 is supplied to the auxiliary battery 6 and the auxiliary device 7.

For example, the auxiliary battery 6 is a 12 V battery and is charged by using the electric power supplied from the alternator 5. The auxiliary battery 6 is coupled to the auxiliary device 7 and supplies the electric power to the auxiliary device 7.

The auxiliary device 7 is a vehicle-mounted device that operates by using the supplied electric power, and examples thereof include a head light, an air conditioner, and a car navigation device. The controller 8 and the display 9 are examples of the auxiliary device 7.

The auxiliary device 7 operates by using the electric power directly supplied from the alternator 5 or the electric power supplied from the auxiliary battery 6.

For example, the controller 8 is an electronic control unit (ECU), that is, a computer that includes a central processing unit (CPU), a read only memory (ROM), a random access memory (RAM), and a non-volatile memory.

The controller 8 loads a program stored in the ROM or the non-volatile memory onto the RAM, runs the program, and consequently diagnoses a malfunction of the alternator 5. A process of diagnosing a malfunction of the alternator 5 will be described later.

When the malfunction of the alternator 5 is found, the controller 8 turns on the display 9 and consequently notifies a driver who drives the vehicle 1 of the malfunction of the alternator 5.

For example, the display 9 is a lamp in a meter panel that is disposed in front of the operator. The controller 8 controls the display 9 such that when the alternator 5 is normal, the display 9 is turned off, and when the alternator 5 is abnormal, the display 9 is turned on.

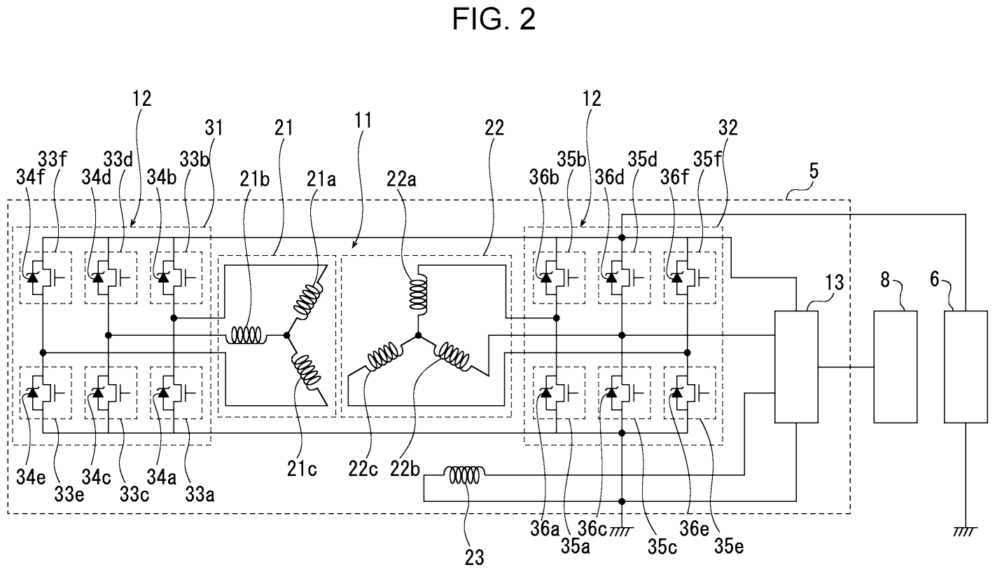

FIG. 2 illustrates the structure of the alternator 5. As illustrated in FIG. 2, the alternator 5 includes a power generator 11, rectifier units 12, and a control circuit 13.

The power generator 11 includes two three-phase alternating-current windings 21 and 22 and an electric field winding 23.

As for the three-phase alternating-current winding 21, three-phase windings (for example, an X-phase winding 21a, a Y-phase winding 21b, and a Z-phase winding 21c) are joined to each other by a star connection and are wound around respective stator cores (not illustrated). Similarly, as for the three-phase alternating-current winding 22, three-phase windings (for example, an X-phase winding 22a, a Y-phase winding 22b, and a Z-phase winding 22c) are joined to each other by a star connection and are wound around respective stator cores (not illustrated) at positions shifted from the three-phase alternating-current winding 21 by an electrical angle of 30 degrees.

The electric field winding 23 is wound around a magnetic field pole (not illustrated) that is disposed to face the inner circumference of the stator core, and forms a rotor. An excitation current is caused to flow through the electric field winding 23, and consequently, the magnetic field pole is magnetized. The three-phase alternating-current windings 21 and 22 generate an alternating-current voltage due to a rotating magnetic field that is generated when the magnetic field pole is magnetized.

The rectifier units 12 include rectifiers 31 and 32. The rectifier 31 is coupled to the three-phase alternating-current winding 21 and rectifies the alternating-current voltage generated by the three-phase alternating-current winding 21 into the direct-current voltage.

The rectifier 31 includes six MOSFETs 33a to 33f that are coupled by bridge coupling. For example, the MOSFET 33a and the MOSFET 33b are coupled to each other in series and form an arm. Similarly, the MOSFET 33c and the MOSFET 33d are coupled to each other in series and form an arm, and the MOSFET 33e and the MOSFET 33f are coupled to each other in series and form an arm. As for the rectifier 31, the three arms are coupled to each other in parallel, and consequently, a three-phase bridge is formed. In the description below, the six MOSFETs 33a to 33f are referred to as the MOSFETs 33 when not being distinguished.

The drains of the MOSFETs 33a, 33c, and 33e are coupled to each other in common and are grounded. The sources of the MOSFETs 33b, 33d, and 33f are coupled to each other in common and are coupled to the anode of the auxiliary battery 6. The cathode of the auxiliary battery 6 is grounded.

The gates of the MOSFETs 33 are coupled to the control circuit 13. The MOSFETs 33 serve as switch elements configured such that current flows between a drain and a source when an on-signal is input from the control circuit 13 into a gate (when a voltage is applied), and current does not flow between the drain and the source when the on-signal is not input from the control circuit 13 into the gate (when no voltage is applied).

A diode 34a is coupled to the MOSFET 33a in parallel in order to protect the MOSFET 33a from back electromotive force (surge). Similarly, diodes 34b to 34f are coupled to the MOSFETs 33b to 33f, respectively, in parallel in order to protect the MOSFETs 33b to 33f from the back electromotive force (surge).

In the description below, the six diodes 34a to 34f are referred to as the diodes 34 when not being distinguished.

The rectifier 32 includes six MOSFETs 35a to 35f that are coupled by bridge coupling. For example, the MOSFET 35a and the MOSFET 35b are coupled to each other in series and form an arm. Similarly, the MOSFET 35c and the MOSFET 35d are coupled to each other in series and form an arm, and the MOSFET 35e and the MOSFET 35f are coupled to each other in series and form an arm. As for the rectifier 32, the three arms are coupled to each other in parallel, and consequently, a three-phase bridge is formed. In the description below, the six MOSFETs 35a to 35f are referred to as the MOSFETs 35 when not being distinguished.

The drains of the MOSFETs 35a, 35c, and 35e are coupled to each other in common and are grounded. The sources of the MOSFETs 35b, 35d, and 35f are coupled to each other in common and are coupled to the anode of the auxiliary battery 6.

The gates of the MOSFETs 35 are coupled to the control circuit 13. The MOSFETs 33 serve as a switch element configured such that current flows between a drain and a source when the on-signal is input from the control circuit 13 into a gate (when a voltage is applied), and current does not flow between the drain and the source when the on-signal is not input from the control circuit 13 into the gate (when no voltage is applied).

Diodes 36a to 36f are coupled to the MOSFETs 35a to 35f, respectively, in parallel in order to protect the MOSFETs 35a to 35f from the back electromotive force (surge).

In the description below, the six diodes 36a to 36f are referred to as the diodes 36 when not being distinguished.

The control circuit 13 is coupled to the gates of the MOSFETs 33 and 35. The control circuit 13 appropriately outputs the on-signal to the gates of the MOSFETs 33 and 35 and consequently controls the operation of the rectifier 31 and the rectifier 32. Consequently, the control circuit 13 causes the rectifier 31 and the rectifier 32 to rectify the alternating-current voltage that is generated by the three-phase alternating-current winding 21 and the three-phase alternating-current winding 22 into the direct-current voltage.

The control circuit 13 is also coupled to the electric field winding 23. The control circuit 13 controls the excitation current that is supplied to the electric field winding 23 and consequently adjusts intensity at which the magnetic field pole is magnetized.

The control circuit 13 measures the power generation current and the power generation voltage when the power generator 11 generates the electric power, and outputs the power generation current and the power generation voltage to the controller 8.

The alternator 5 includes sensors that measure a temperature, and the rotation speed and load torque of the rotor. Measurement values measured by the sensors are output to the controller 8 via the control circuit 13.

In some cases, the power generation current, the power generation voltage, the temperature, the rotation speed, and the load torque of the alternator 5 may be collectively referred to below as information about the state of the operation of the alternator 5.

The controller 8 is coupled to the control circuit 13, instructs the control circuit 13 to request the operation of the alternator 5, and acquires the information about the state of the operation of the alternator 5. The controller 8 diagnoses a malfunction of the alternator 5, based on the acquired information about the state of the operation.

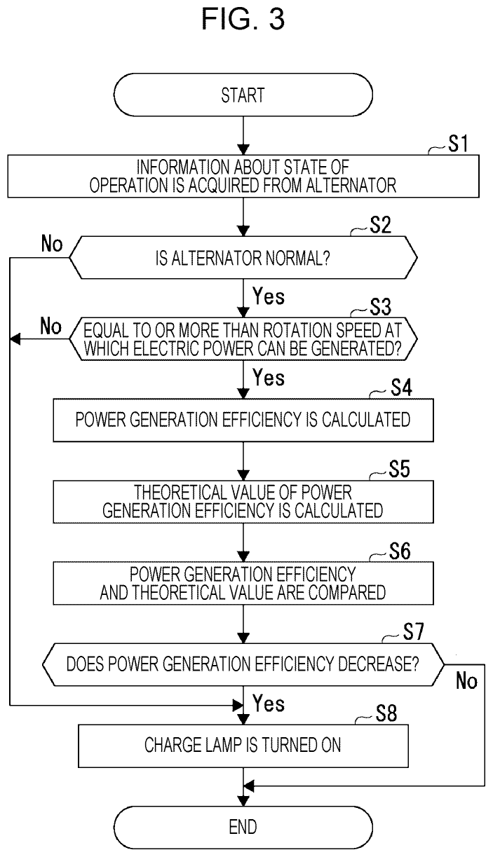

FIG. 3 is a flowchart illustrating the flow of a malfunction diagnosing process performed by the controller 8. As illustrated in FIG. 3, the malfunction diagnosing process starts, and the controller 8 then acquires the information about the state of the operation from the alternator 5 at a step S1.

At a step S2, the controller 8 determines whether the alternator 5 is normal. For example, whether the power generation voltage decreases and whether communication with the alternator 5 is normal are determined.

When the alternator 5 is normal (Yes at the step S2), at a step S3, the controller 8 determines whether the rotation speed of the alternator 5 is equal to or more than a rotation speed at which the electric power can be generated. The rotation speed at which the electric power can be generated is a rotation speed at which the alternator 5 can generate the electric power.

When the rotation speed of the alternator 5 is equal to or more than the rotation speed at which the electric power can be generated (Yes at the step S3), at a step S4, the controller 8 calculates the power generation efficiency of the alternator 5. For example, the controller 8 calculates input energy input into the alternator 5 and output energy acquired from the power generated by the alternator 5 and calculates the power generation efficiency by dividing the calculated output energy by the input energy.

The input energy is kinetic energy input from the engine 2 in order to rotate the rotor of the alternator 5 and is calculated as Expression (1) below:

Input Energy=Load Torque of Alternator 5×Rotation Speed of Alternator 5×π/30 (1)

The output energy is electrical energy acquired from the power generated by the alternator 5 and is calculated as Expression (2) below:

Output Energy=Power Generation Current of Alternator 5×Power Generation Voltage of Alternator 5 (2)

The controller 8 calculates the input energy by using Expression (1) and calculates the output energy by using Expression (2). The controller 8 calculates the power generation efficiency by using Expression (3) below:

Power Generation Efficiency=Output Energy/Input Energy (3)

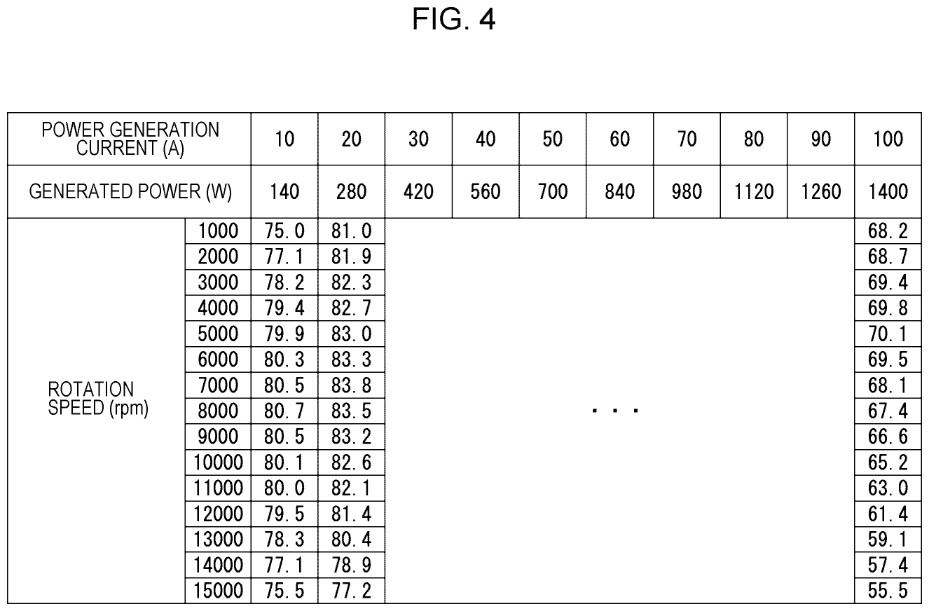

FIG. 4 illustrates the theoretical value map of the power generation efficiency.

At a step S5, the controller 8 refers the theoretical value map of the power generation efficiency illustrated in FIG. 4 and calculates the theoretical value of the power generation efficiency, based on the power generation current, the power generation voltage, the rotation speed, and the temperature of the alternator 5 that are acquired at the step S1.

The theoretical value is the power generation efficiency that is theoretically acquired when the alternator 5 operates at a predetermined power generation current, power generation voltage, rotation speed, and temperature.

The controller 8 stores, in the ROM, the theoretical value map of the power generation efficiency illustrated in FIG. 4. The theoretical value maps are provided for different temperatures, and the theoretical value maps for the different temperatures are stored in the ROM.

As illustrated in FIG. 4, the theoretical value map represents the theoretical values of the power generation efficiency for respective power generation currents, power generation voltages, rotation speeds, and temperatures of the alternator 5. The power generation voltage is controlled by the controller 8 so as to be constant (here, about 14 V), and FIG. 4 illustrates generated power (power generation voltage×power generation current).

The controller 8 calculates the theoretical value by interpolating a value that is acquired from the theoretical value map, based on the power generation current, the power generation voltage, the rotation speed, and the temperature of the alternator 5 that are acquired at the step S1.

At a step S6, the controller 8 compares the power generation efficiency calculated at the step S4 and the theoretical value of the power generation efficiency calculated at the step S5. For example, whether a difference between the power generation efficiency calculated at the step S4 and the theoretical value of the power generation efficiency calculated at the step S5 is equal to or less than a predetermined percentage (a ratio to the theoretical value) is calculated.

At a step S7, the controller 8 determines whether the power generation efficiency of the alternator 5 decreases based on the result of comparison at the step S6. Here, whether the difference from the theoretical value is more than the predetermined percentage is determined.

When the power generation efficiency of the alternator 5 does not decrease (No at the step S7), the controller 8 ends the malfunction diagnosing process.

When the alternator 5 is abnormal (No at the step S2), when the rotation speed of the alternator 5 is less than the rotation speed at which the electric power can be generated (No at the step S3), or when the power generation efficiency decreases (Yes at the step S7), the controller 8 performs a process at a step S8.

At the step S8, the controller 8 causes the display 9 indicating that the alternator 5 is abnormal to be turned on and ends the malfunction diagnosing process.

As described above, the vehicle 1 diagnoses a malfunction based on the power generation efficiency of the alternator 5. The MOSFETs 33 and 35 are used for the rectifiers 31 and 32 of the alternator 5. The diodes 34 and 36 are coupled in parallel to the MOSFETs 33 and 35. Thus, when the MOSFETs 33 and 35 malfunction, an electric current flows through the diodes 34 and 36, and the power generation efficiency decreases, but the power generation can be continued.

Accordingly, an open failure in the MOSFETs 33 and 35 cannot be determined by simply monitoring the power generation current and the power generation voltage. When the open failure occurs in the MOSFETs 33 and 35, an electric current flows through the diodes 34 and 36, and the electric power is consequently generated, the power generation efficiency decreases.

In view of this, the vehicle 1 can determine that the open failure occurs in the MOSFETs 33 and 35, that is, the alternator 5 malfunctions by diagnosing a malfunction based on the power generation efficiency of the alternator 5.

### 2. Modification

The embodiment is described above but is not limited to specific examples described above, and various structures can be included.

For example, according to the embodiment described above, the controller 8 acquires the power generation current, the power generation voltage, the rotation speed, the load torque, and the temperature of the alternator 5 from the control circuit 13. However, the controller 8 may directly acquire one or more pieces of such information.

According to the embodiment described above, the theoretical value of the power generation efficiency of the alternator 5 is calculated by using the theoretical value map. However, the theoretical value may be calculated by using another method, provided that the theoretical value of the power generation efficiency of the alternator 5 can be calculated.

According to the embodiment described above, the power generation efficiency is calculated from the input energy and the output energy of the alternator 5. However, the power generation efficiency may be calculated by using another method, provided that the power generation efficiency of the alternator 5 can be calculated.

### 3. Summary of Embodiment

As described above, the malfunction-diagnosing apparatus (the vehicle 1) according to the embodiment includes the alternator 5 and the controller 8 that diagnoses a malfunction of the alternator 5. The alternator 5 includes the power generator 11 that generates the alternating-current voltage by using the motive power output from the engine 2 and the rectifiers 31 and 32 that rectify the alternating-current voltage into the direct-current voltage. The rectifiers 31 and 32 include the field-effect transistors (the MOSFETs 33 and 35) and the diodes 34 and 36 that are coupled in parallel to the field-effect transistors. The controller diagnoses the malfunction, based on the power generation efficiency of the alternator 5.

This enables the vehicle 1 to diagnose an open failure in the MOSFETs 33 and 35 even when the open failure occurs in the MOSFETs 33 and 35, an electric current flows through the diodes 34 and 36, and the alternator 5 consequently generates the electric power. That is, the vehicle 1 enables a malfunction of the alternator 5 that uses the MOSFETs 33 and 35 to be diagnosed.

The controller 8 calculates the power generation efficiency, based on the input energy input into the alternator 5 and the output energy acquired from the power generated by the alternator 5.

Consequently, the controller 8 calculates the power generation efficiency, based on the actual input energy and output energy. Thus, the power generation efficiency can be calculated in real time with precision.

The controller 8 compares the calculated power generation efficiency and the theoretical value of the power generation efficiency of the alternator 5 and determines the malfunction when the difference between the calculated power generation efficiency and the theoretical value is more than the predetermined percentage.

This enables the controller 8 to accurately calculate a decrease in the power generation efficiency of the alternator 5.

The theoretical value is calculated based on the power generation current, the power generation voltage, the rotation speed, and the temperature of the alternator 5.

The controller 8 can calculate the theoretical value of the power generation efficiency of the alternator 5 with precision by using the theoretical value map illustrated in FIG. 4.

When the alternator 5 is abnormal, the controller 8 reports that the alternator 5 is abnormal by using the display 9.

The controller 8 causes the display 9 to be turned on when the malfunction of the alternator 5 is detected and consequently enables the driver who drives the vehicle 1 to readily recognize that the alternator 5 malfunctions.

According to the present disclosure, malfunction of an alternator using a field-effect transistor can be diagnosed.

The controller 8 illustrated in FIG. 1 can be implemented by circuitry including at least one semiconductor integrated circuit such as at least one processor (e.g., a central processing unit (CPU)), at least one application specific integrated circuit (ASIC), and/or at least one field programmable gate array (FPGA). At least one processor can be configured, by reading instructions from at least one machine readable tangible medium, to perform all or a part of functions of the controller 8. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and a SRAM, and the non-volatile memory may include a ROM and a NVRAM. The ASIC is an integrated circuit (IC) customized to perform, and the FPGA is an integrated circuit designed to be configured after manufacturing in order to perform, all or a part of the functions of the modules illustrated in FIG. 1.

1. A malfunction-diagnosing apparatus comprising:
an alternator; and
a controller configured to diagnose a malfunction of the alternator,
wherein the alternator comprises a power generator configured to generate an alternating-current voltage by using motive power output from an engine, and a rectifier configured to rectify the alternating-current voltage into a direct-current voltage,
wherein the rectifier comprises a field-effect transistor, and a diode coupled in parallel to the field-effect transistor, and
wherein the controller is configured to diagnose the malfunction, based on power generation efficiency of the alternator.

2. The malfunction-diagnosing apparatus according to claim 1,
wherein the controller is configured to calculate a calculation value of the power generation efficiency, based on input energy input into the alternator and output energy acquired from power generated by the alternator.

3. The malfunction-diagnosing apparatus according to claim 2,
wherein the controller is configured to
compare the calculation value and a theoretical value of the power generation efficiency of the alternator, and
determine the malfunction when a difference between the calculation value and the theoretical value is more than a predetermined percentage.

4. The malfunction-diagnosing apparatus according to claim 3,
wherein the theoretical value is calculated based on a power generation current, a power generation voltage, a rotation speed, and a temperature of the alternator.

5. The malfunction-diagnosing apparatus according to claim 1,
wherein the controller is configured to, when the alternator is abnormal, report that the alternator is abnormal by using a display.

6. The malfunction-diagnosing apparatus according to claim 2,
wherein the controller is configured to, when the alternator is abnormal, report that the alternator is abnormal by using a display.

7. The malfunction-diagnosing apparatus according to claim 3,
wherein the controller is configured to, when the alternator is abnormal, report that the alternator is abnormal by using a display.

8. The malfunction-diagnosing apparatus according to claim 4,
wherein the controller is configured to, when the alternator is abnormal, report that the alternator is abnormal by using a display.

9. A malfunction-diagnosing apparatus comprising:
an alternator; and
circuity configured to diagnose a malfunction of the alternator,
wherein the alternator comprises a power generator configured to generate an alternating-current voltage by using motive power output from an engine, and a rectifier configured to rectify the alternating-current voltage into a direct-current voltage,
wherein the rectifier comprises a field-effect transistor, and a diode coupled in parallel to the field-effect transistor, and
wherein the circuity is configured to diagnose the malfunction, based on power generation efficiency of the alternator.
